(19) United States
(12) Patent Application Publication
(10) Pub. No.: US 2006/0073635 A1
(43) Pub. Date: Apr. 6, 2006

(54) Three dimensional package type stacking for thinner package application

(76) Inventors: Chao-Yuan Su, Koahsiung (TW); Pei-Haw Tsao, Tai-chung (TW); Chender Huang, Hsin-Chu (TW)

Correspondence Address: DUANE MORRIS, LLP;IP DEPARTMENT, 30 SOUTH 17TH STREET, PHILADELPHIA, PA, 19103-4196, US

(21) Appl. No.: 10/951,428

(22) Filed: Sep. 28, 2004

(51) Int. Cl. H01L 21/50

(52) U.S. Cl. 438/109

(57) ABSTRACT

A stacked semiconductor device, and method of making, having a plurality of semiconductor chips of desired sizes stacked as one package, a first semiconductor chip is mounted on a first substrate. Solder balls are connected to contacts on the upper surface of the first substrate and a non-conductive layer is provided overlaying the first substrate and the first semiconductor chip. The solder balls are secured in cavities formed in the layer and extend beyond the top surface of the layer. A second semiconductor chip mounted on a second substrate is stacked on the layer with contacts on the lower surface of the second substrate in electrical contact with the extended portion of the solder balls, thereby connecting the second semiconductor chip with the first semiconductor chip.

### BACKGROUND

In recent years, portable electronic devices such as mobile telephones and non-volatile memory media such as IC memory cards have become smaller and smaller. Along with this trend, there have been demands for devices and memory media having a smaller number of components and a smaller size. Accordingly, it is desired to develop a technique of effectively packaging semiconductor chips that are main components constituting the aforementioned electronic devices and memory media. Examples of such packages that satisfy the above demands include a chip scale package (CSP) that is comparable in size to a semiconductor chip, a multi-chip package (MCP)that accommodates a plurality of semiconductor chips in one package, and a three dimensional (3D) package that incorporates at least a smaller second package within a larger first package.

3D packages allow more semiconductor functions per unit of area of board space and more semiconductor functions per unit of volume of application space, as well as significant size and weight reductions. Including two or more die in one package decreases the number of components mounted on a given printed circuit board. 3D packages provide a single package for assembly, test and handling which reduces package cost.

3D packages also allow a low overall cost without requiring cutting edge technology, because a desired set of functions can be included within the 3D package without having to put all of the functions in a single IC chip. Also, because die to die interconnects can be made within the package, the package I/O and the printed circuit board (PCB) routing are simplified. Because multiple dies are included with the footprint of a single 3D package, the length and/or width of the PCB can be reduced.

The 3D package or MCP is realized by stacking and turning a plurality of semiconductor chips and/or packages into one package. This technique is represented by a stacked multi-chip package (S-MCP).

FIG. 1a shows the structure of a conventional S-MCP in which two semiconductor chips are stacked. As shown in FIG. 1a, a lower semiconductor chip 2 is mounted on a package substrate 4, and an upper semiconductor chip 6 that is smaller than the lower semiconductor chip 2 is stacked thereon. Electrodes of the semiconductor chips 2 and 6 are connected to the pads of the substrate 4 by bonding wires 8. The pads of the substrate 4 are electrically connected to external connecting terminals 10 thereby providing input/output connections between electrodes of the package and the semiconductor chips. These pads are typically positioned around substantially all of the available peripheral area of the package or at least two sides of the package. The semiconductor chips 2 and 6 and the bonding wires 8 may also be encapsulated by an encapsulation resin 12.

In the above conventional S-MCP, however, the upper semiconductor chip 6 must be smaller than the lower semiconductor chip 2. The upper semiconductor chip 6 should be small enough not to cover the electrodes of the lower semiconductor chip 2. On the other hand, if the upper semiconductor chip 6 is too much smaller than the lower semiconductor chip 2, the distance between the electrodes of the upper semiconductor chip 6 and the pads of the substrate 4 becomes too long to perform a proper wire bonding operation.

In the configuration described above, semiconductor chips of the same size (i.e., of the same type) cannot be stacked if both are to be wire bonded to the package substrate. As the sizes of the semiconductor chips that can be stacked are limited, the types of the semiconductor chips that can be employed in the S-MCP are also limited.

Other types of prior art stacked packages are shown in FIGS. 1b-1d. These types include a “multiple package stack” as shown in FIG. 1b, and other known stacked packages shown in FIGS. 1c and 1d. Each of these prior art types suffer from thicker package type and fixed stacked package dimensions.

### SUMMARY

Some embodiments include a method of electrically connecting a plurality of semiconductor chips in a vertical stack. The method includes providing a first semiconductor chip carried by a first package substrate, the first substrate having plural contacts on the upper surface thereof and positioning one of plural conductive bumps or spheres on each of the plural contacts of the first substrate. The method also includes providing a layer of non-conductive material overlying the first chip and exposed substrate, and partially covering the conductive spheres. A second semiconductor chip on a second package substrate is provided. The second substrate has exposed contacts on its lower surface. The second substrate is positioned on the layer so that the exposed contacts are in electrical contact with the conductive bumps or spheres.

In some embodiments, a package comprises a first semiconductor chip carried by a first package substrate, the first substrate having plural contacts on an upper surface; plural conductive spheres, one on each of the plural contacts of the first substrate; and a layer of non conducting material overlaying the first chip and the first substrate partially covering the conductive spheres. The device also includes a second semiconductor chip on a second substrate, the second substrate having exposed contacts on the lower surface wherein the second substrate is positioned on the layer so that the exposed contacts of the second substrate contact the conductive spheres.

In some embodiments, a vertical stack of semiconductor chips form a three dimensional package. The vertical stack has a first semiconductor chip wire bonded to a upper surface of a first substrate, a second semiconductor chip wire bonded to a second upper surface of a second substrate above the first semiconductor chip, wherein the second semiconductor chip is electrically connected to the first semiconductor chip by electrical paths through the second substrate. An electrically non-conductive layer is positioned between the first and second substrates, the layer containing cavities securing conductive spheres that electrically connect the second substrate to contacts on the upper surface of the first substrate and structurally connect the first substrate with the second substrate.

These features and other advantages of the disclosed subject matter will be readily apparent to one skilled in the art to which the disclosure pertains from a perusal or the claims, the appended drawings, and the following detailed description of the preferred embodiments.

### BRIEF DESCRIPTION OF THE DRAWINGS

FIGS. 1a-1d are representations of prior art three dimensional multi-chip packages.

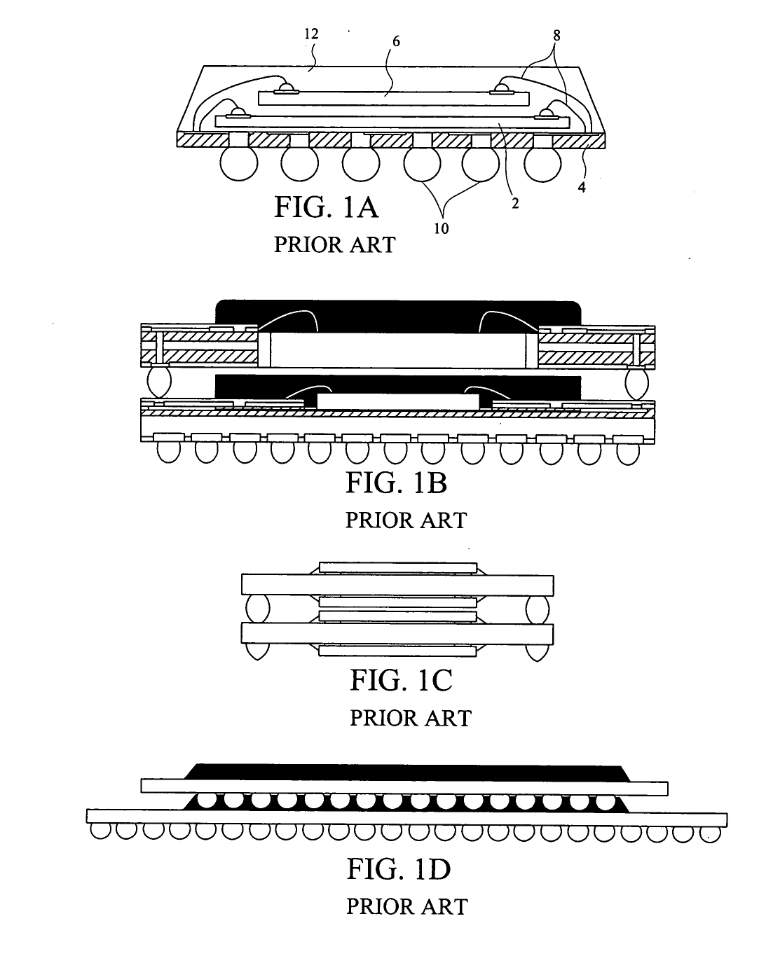

FIGS. 2a-2d are representations of a method for making a three dimensional chip scale package according to an embodiment of the disclosed subject matter.

FIG. 3 is a representation of a three dimensional chip scale package according to an embodiment of the disclosed subject matter.

### DETAILED DESCRIPTION

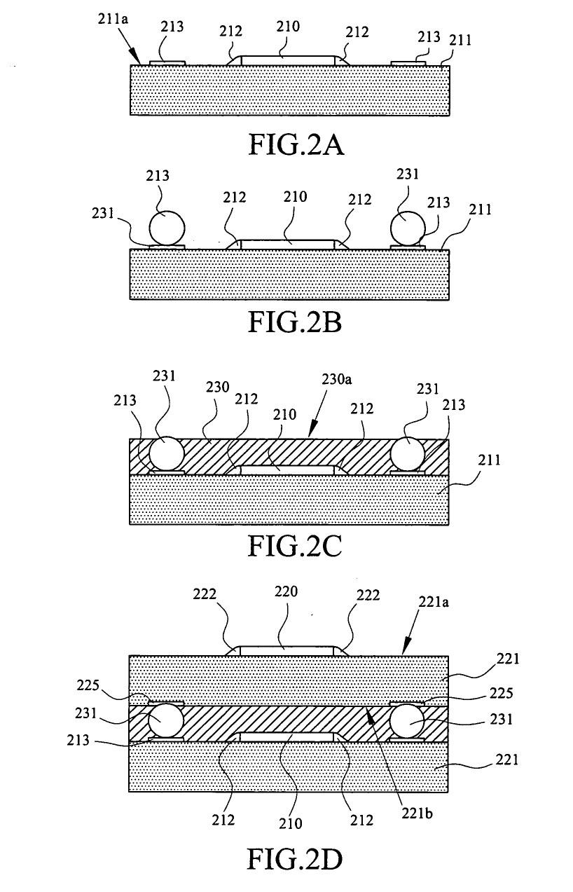

An embodiment of a method for making a three dimensional (3D) package of stacked semiconductors is shown in FIGS. 2a-2d. A first semiconductor chip 210 is mounted to a first electrically non-conductive substrate 211. The first semiconductor chip 210 is wire bonded through wires 212 to the first substrate plural contacts 213 formed on the upper surface 211a. The plural contacts 213 are typically masked and etched on the upper surface 211a; however, other methods of forming the plural contacts 213 are also envisioned.

As shown in FIG. 2b, solder bumps or conductive spheres 231, typically solder balls are positioned on each of the plural contacts 213 of the first substrate 211. The conductive bumps or spheres 231 may be of a diameter such that their upper portion exceeds the vertical height of the top surface of the first semiconductor chip 210 by a predetermined amount. The predetermined amount can be a function of materials, heat dissipation, electrical isolation and other design factors. Alternatively, solder bumps or contacts of a sufficient height to be exposed at the top surface of the first semiconductor chip 210 may be used. The conductive bumps or spheres 231 are preferably attached to the upper surface 211a of the first substrate 211 by using a plant solder ball technique, which is known in the art. The use of the terms “solder balls” and spheres in this disclosure are meant to include all generally round geometries and should not be read to exclude all but perfect geometric spheres. Further, solder bumps that are not of a generally spherical shape may also be used, i.e., bumps having a near-rectangular or cubical shape.

As illustrated in FIG. 2c, a non-conductive layer 230 of material such as a molding compound or encapsulant is provided to overlie the first semiconductor chip 210 and exposed upper surface 211a of the first substrate 211 and encapsulate the bonding wires 212. The exposed upper surface 211a is that portion of the first substrate 211 that is not covered by the first semiconductor chip 210. The height of the over mold layer 230 may be less than or equal to the height of the conductive spheres 231. Preferably, the over mold layer 230 has a uniform height (relative to the upper surface of the package substrate) sufficient to cover and insulate the first semiconductor chip 210 and bonding wires 212 from a semiconductor chip or package subsequently stacked thereon, and the height of layer 230 does not completely cover the bumps or conductive spheres 231. That is, the top surface of the over mold layer 230 is planarized, except for the tops of the conductive bumps or spheres protruding therethrough. Thus the top surface 230a of the over mold layer 230 may lie below the upper portion of the bumps or conductive spheres 231. The exposed upper portion of the conductive spheres is of a height such that it can contact the contact pads on the underside of another substrate or package (e.g., a land grid array, or LGA, package) stacked on top of the over mold layer 230. The conductive spheres 231 may be secured in cavities or encapsulated by the molding compound within the layer 230. Embodiments of the disclosed subject matter may or may not rely upon the conductive spheres 231 to support the substrates of packages stacked on top of the first semiconductor chip 210 and substrate 211. In an alternative embodiment of the present invention, the height of the non-conductive layer 230 may cover or overlie the conductive spheres 231 whereupon the layer 230 may be selectively etched by known etching methods to form openings (not shown) in the layer 230 that allow the contact pads on the underside of another substrate or package to project into the openings and contact the conductive spheres 231.

The layer 230 may be formed by molding the compound directly over the first semiconductor chip 210 and substrate 211, in which case, a resin or similar material is poured onto the upper surface of the chip 210, substrate 211 and conductive spheres 231 and allowed to cure or harden. When the layer 230 is formed in this manner, the wires 212 are also advantageously encapsulated. In other embodiments, the layer 230 may also be machined, cast, etched or molded prior to or concurrently with the positioning of the chip 210, substrate 211 and conductive spheres 231. If the layer 230 is machined, cast, etched, or molded in advance, a cavity is formed to accommodate the bonding wires 212. The layer 230 also serves to bond the first substrate 211 to a second substrate. Such bonding may be achieved by using a material for the layer 230 that bonds to the second package substrate 221 or by applying an adhesive between the top surface of the layer 230 and the bottom surface of the second package substrate 221.

As shown in FIG. 2d, a second package (e.g., an LGA package) having a second semiconductor chip 220 located on a second package substrate 221 is wire bonded by wires 222 to contacts (not shown) on the top surface 221a of the second substrate 221. The second package substrate 221 has exposed electrodes or contacts 225 on the lower surface 221b of the second substrate 221 that are in electrical connection with contact pads on the upper surface 221a, some of which are wire bonded to the second semiconductor chip 220. The second package substrate 221 is positioned in relationship to the layer 230 so that the exposed contacts 225 of the second substrate 221 contact the upper portion of the conductive spheres 231.

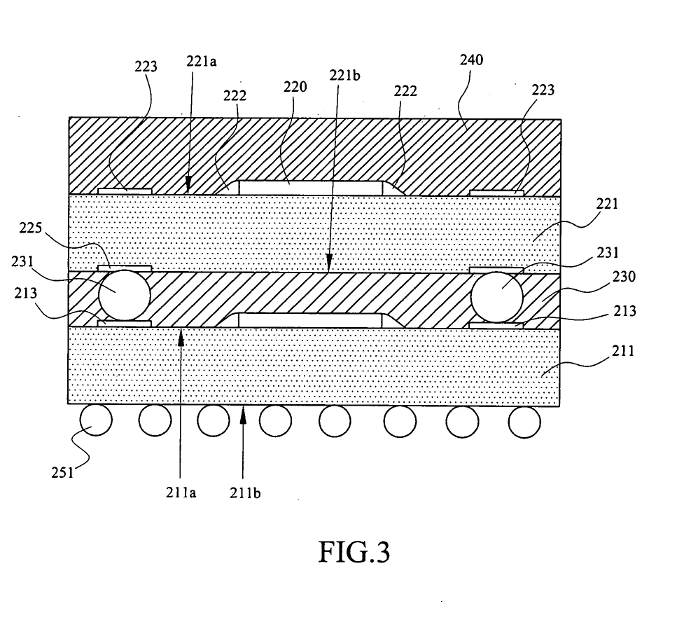

An embodiment of the disclosed 3D package formed with a plurality of semiconductor chips in a vertical stack is shown in FIG. 3. The 3D package includes a first semiconductor chip 210 carried and electrically connected by a first electrically non-conductive package substrate 211, the first substrate 211 having plural contacts 213 on its upper surface 211a. A conductive sphere 231 resides, in electrical contact, on at least some of the contacts 213 of the first substrate 211. Only those contacts associated with wire bonding of the second chip 220 need to have a conductive sphere 231; however, for production it is envisioned that most or all of the contacts 213, whether used or not, will be electrically connected by a conductive sphere 231 to allow for more universal use.

A non-conductive layer 230 of material overlies the first semiconductor chip 210 and the exposed upper surface 211a of the first substrate 211 as shown in FIG. 3. The layer 230 has a uniform height sufficient to insulate (i.e., cover) the first semiconductor chip 210 from any package, semiconductor chip or substrate stacked thereon. The height has a maximum limit such that it does not cover or overlie the conductive spheres 231, or interfere with the contact between the conductive spheres 231 and conductive pads 225. For purposes of the disclosure, the conductive sphere 231 and any conductive pad 225 associated with the conductive sphere 231 will be collectively referred to as a conductive sphere 231.

As shown in FIG. 3, a second semiconductor chip 220 is mounted on a second substrate 221 and electrically connected to contacts 223 on the upper surface 221a of the second substrate 221 through wire bonding by wires 222. The contacts 223 on the upper surface 221a of the second substrate 221 are also in electrical contact with exposed contacts 225 on the lower surface 221b of the second substrate 221. The contacts on the first or second substrates are formed in a typical manner such as masking and etching, or other method known in the art. In another embodiment, the second semiconductor chip 220 is a Static Random Access Memory (SRAM) chip (e.g., land grid array (LGA), bump chip carrier (BCC) or other type of grid array or leadless chip carrier).

The second substrate 221 is positioned on the layer 230, and the layer 230 so constructed, enables the exposed contacts 225 of the second substrate 221 to contact the conductive spheres 231. A second layer 240 also overlies the exposed upper surface 221a of the second substrate 221 and encapsulates the second semiconductor chip 220. The second layer 240 may also have a uniform height. In stacks with more than two semiconductor chips, the second molding compound layer 240 may have the same characteristics of the first, except it will be located between the second substrate 221 and a third package substrate (not shown). Also, solder bumps or conductive spheres will electrically connect contacts on the upper surface 221a of the second package substrate 221 with contacts in the lower surface of the third substrate. While the embodiments described herein relate to double and triple stacking, any number of chips can be stacked in the described process.

The lower surface 211b of the first substrate 211 also has a plurality of contacts (not shown) that connect to additional conductive spheres that provide attachment and electrical connection for the CSP to a circuit board (not shown). For example, the package may be a ball grid array package with a rectangular array of solder balls on the lower surface 211b.

The result of the configuration and method described above is a 3D package that has a thinner vertical thickness and can provide more options in stacked configurations.

It will be understood that various changes in the details, materials, and arrangements of the parts which have been described and illustrated above in order to explain the nature of this disclosure may be made by those skilled in the art without departing from the principle and scope of the disclosure as recited in the appended claims.

What we claim is:

1. A method of electrically connecting a plurality of semiconductor chips in a vertical stack comprising:
(a) providing a first semiconductor chip carried by a first electrically non-conductive substrate, the first substrate having plural contacts on the upper surface thereof;
(b) positioning one of plural conductive bumps or spheres on each of the plural contacts of the first substrate;
(c) providing a layer of non-conductive material overlying the first chip, and an exposed portion of the first substrate such that top portions of the conductive spheres are exposed;
(d) providing a second semiconductor chip on a second substrate, the second substrate having exposed contacts on the lower surface thereof;
(e) positioning the second substrate on the layer so that the exposed contacts of the second substrate contact the conductive bumps or spheres.

2. The method of claim 1, wherein the layer is formed by molding.

3. The method of claim 1, wherein the first semiconductor chip is wire bonded to the first substrate.

4. The method of claim 1, wherein the second semiconductor chip is wire bonded to the second substrate.

5. The method of claim 1, further comprising the step of positioning conductive bumps or spheres on the lower surface of the first substrate.

6. The method of claim 1, comprising the step of structurally supporting the second substrate with the layer.

7. The method of claim 2, comprising the step of etching the layer to a height sufficient to insulate the first chip from any device stacked thereon and the height being insufficient to cover the conductive bumps or spheres.

8. The method of claim 1, comprising the step of machining the layer.

9. The method of claim 1, wherein the conductive spheres are solder balls.

10. The method of claim 1, comprising the step of securing the conductive spheres in cavities in the layer.

11. The method of claim 1, comprising the step of bonding the layer to the upper surface of the first substrate and to the lower surface of the second substrate.

12. The method of claim 1, comprising the step of providing a second layer of non-conductive material overlying the second chip, and overlying an exposed portion of the second substrate to a uniform height.

13. The method of claim 1, wherein at least one of the conductive spheres contacts a conductive contact pad.

14. The method of claim 3, comprising the step of encapsulating the bonding wires of the first semiconductor chip with the layer.

15. An package comprising:
a first semiconductor chip carried by a first electrically non-conductive substrate, the first substrate having plural contacts on an upper surface thereof;
plural conductive spheres, one on each of the plural contacts of the first substrate;
a layer of non conducting material overlying the first chip and an exposed upper surface of the first substrate such that top portions of the conductive spheres are exposed;
a second semiconductor chip on a second substrate, the second substrate having exposed contacts on the lower surface thereof;
wherein the second substrate is positioned on the layer so that the exposed contacts of the second substrate contact the conductive spheres.

16. The package of claim 15, wherein the conductive spheres are solder balls.

17. The package of claim 15, further comprising a second plurality of conductive bumps or spheres positioned on the lower surface of the first substrate.

18. The package of claim 15, further comprising a third semiconductor chip on a third substrate, and a second layer of non conducting material between the second chip and the lower surface of the third substrate.

19. The package of claim 15, wherein the conductive spheres do not structurally support the second substrate.

20. The package of claim 15, wherein the layer structurally supports the second substrate.

21. The package of claim 15, wherein the layer has a uniform height.

22. The package of claim 15, further comprising electrical paths connecting the plural contacts on the upper surface of the first substrate to plural lower contacts on the lower surface of the first substrate.

23. The package of claim 15, further comprising electrical paths connecting a second plurality of contacts on the upper surface of the second substrate and the exposed contacts on the lower surface of the second substrate.

24. The package of claim 15, wherein the second semiconductor chip is a static random access memory chip.

25. The package of claim 15, wherein the conductive spheres are structurally secured in cavities in the layer.

26. The package of claim 15, wherein the layer is of a material that bonds to both the upper surface of the first substrate and to the lower surface of the second substrate.

27. The package of claim 15, comprising a second layer of non conducting material overlaying the second chip and an exposed upper surface of the second substrate and having a uniform height.

28. The package of claim 15, wherein the layer is a resin.

29. In a vertical stack of semiconductor chips having a first semiconductor chip wire bonded to an upper surface of a first substrate, a second semiconductor chip wire bonded to a second upper surface of a second substrate above the first semiconductor chip, the second semiconductor chip electrically connected to the first semiconductor chip by electrical paths through the second substrate, the improvement comprising: an electrically non-conductive layer positioned between the first and second substrates, said layer containing cavities securing conductive bumps or spheres that electrically connect the second substrate to contacts on the upper surface of the first substrate, and said layer structurally connecting the first substrate with the second substrate.

30. A method, comprising the steps of:
providing a substrate having a die thereon with contacts of the die wire bonded to first contacts on a top surface of the substrate;
placing a plurality of solder bumps or balls on respective second contacts on the top surface of the substrate;
over-molding the die with a layer of material and exposing top portions of the conductive bumps or spheres; and
mounting a package on the layer of material, with conductive pads of the package in contact with the top surfaces of respective ones of the conductive bumps or spheres.

31. The method of claim 30, further comprising reflowing the conductive bumps or spheres to mechanically and electrically connect the pads of the package to the second contacts of the substrate.

32. The method of claim 30, wherein the package is a land grid array or bump chip carrier package.

33. The method of claim 30, wherein the layer of material has a height that is less than an height of the conductive bumps or spheres.

34. The method of claim 30, wherein the step of exposing top portions of the conductive bumps or spheres includes etching a top surface of the layer.
